(19) United States
(12) Patent Application Publication
(10) Pub. No.: US 2013/0001636 A1
(43) Pub. Date: Jan. 3, 2013

(54) LIGHT-EMITTING DIODE AND METHOD FOR FORMING THE SAME

(75) Inventors: Hsin-Ming LO, Pingtung County (TW); Shih-Chang SHEI, Tainan City (TW)

(73) Assignee: ACEPLUX OPTOTECH INC., Tainan City (TW)

(21) Appl. No.: 13/446,588

(22) Filed: Apr. 13, 2012

(30) Foreign Application Priority Data
Jun. 28, 2011 (TW) 100122660

(51) Int. Cl. H01L 33/52; H01L 33/40

(52) U.S. Cl. 257/100; 438/26; 257/E33.059; 257/E33.061

(57) ABSTRACT

A light-emitting diode includes: an epitaxial substrate; a light-emitting unit including a lower semiconductor layer, and at least two epitaxial units that are separately formed on the lower semiconductor layer, the epitaxial units cooperating with the lower semiconductor layer to define two light-emitting sources that are capable of emitting different colors of light; and an electrode unit including a first electrode which is formed on an exposed portion of the lower semiconductor layer exposed from the epitaxial units, and at least two second electrodes each of which is formed on a corresponding one of the epitaxial units. A method for forming a light-emitting diode is also disclosed.

### CROSS-REFERENCE TO RELATED APPLICATION

This application claims priority of Taiwanese application no. 100122660, filed on Jun. 28, 2011.

### BACKGROUND OF THE INVENTION

1. Field of the Invention

This invention relates to a light-emitting diode and a method for forming the same, more particularly to a light-emitting diode that is capable of emitting different colors of light, and a method for forming the same.

2. Description of the Related Art

Light-emitting diodes (LEDs) have advantages of low electricity consumption, long service life, and high response speed in addition to a relatively small volume. Thus, the LEDs can easily conform with the design requirements of an electronic device, and have been widely used in devices of communication, information, consumer electronics, illumination, and display. In particular, since the white light LEDs have superior energy saving property, the same have a wide range of applications and the development thereof has become increasingly important.

In general, the white light LED can be formed using any of three main approaches.

In the first approach, a single LED die, which emits blue or UV light, is added with fluorescent powders which can emit excitation light that is produced in response to the blue or UV light and that has a color different from the light from the LED die. The light from the LED die and the excitation light of the fluorescent powders are mixed to produce the white light. In a commercially available LED, the LED die usually emits blue light and the fluorescent powders can produce yellow light. However, the LED made using the first approach has problems of poor luminance and chrominance.

In the second approach, multiple LED dies, which emit different colors of light (such as red, green and/or blue light), are packaged in a single LED. The lights from the different LED dies are mixed to produce white light. However, when two LED dies (a blue light LED die+a yellow light LED die, a blue light LED die+a yellow green light LED die, or a blue green light LED die+a yellow light LED die) are packaged, the LED may have poor color rendering properties. When three or four LED dies are packaged, the LED may have better working efficiency and color rendering. However, the LED dies, which emit different colors of light, have different driving voltages, intensities of light output, temperature characteristics, and service life, and thus not all of the LED dies are controlled in adequate conditions. Besides, the LED with multiple LED dies needs increased packaging space and incurs higher manufacturing cost, and thus, the applications of such LED are somewhat limited.

In the third approach, multiple light-emitting films are stacked one above the other in a single LED die to emit different colors of light, and the different colors of light can be mixed to produce white light. In this case, the LED has better color rendering and the packaging space can be minimized. However, multiple quantum wells will be formed in the stacked multiple light-emitting films, thereby increasing the threshold voltage (V_{f}) of the LED and reducing the light-emitting efficiency of the LED die.

### SUMMARY OF THE INVENTION

Therefore, an object of the present invention is to provide a light-emitting diode and a method for forming the same that can overcome the aforesaid drawbacks associated with the prior art.

According to a first aspect of this invention, a light-emitting diode comprises:

an epitaxial substrate;

a light-emitting unit including a lower semiconductor layer, and at least two epitaxial units that are separately formed on the lower semiconductor layer, the epitaxial units cooperating with the lower semiconductor layer to define two light-emitting sources that are capable of emitting different colors of light; and

an electrode unit including a first electrode which is formed on an exposed portion of the lower semiconductor layer exposed from the epitaxial units, and at least two second electrodes each of which is formed on a corresponding one of the epitaxial units.

According to a second aspect of this invention, a method for forming a light-emitting diode comprises:

(a) forming over an epitaxial substrate a lower semiconductor layer;

(b) forming a first epitaxial unit on the lower semiconductor layer, the first epitaxial unit and the lower semiconductor layer defining a first light-emitting source;

(c) forming a second epitaxial unit on the lower semiconductor layer in a manner that the first and second epitaxial units are spaced apart from each other, the second epitaxial unit and the lower semiconductor layer defining a second light-emitting source, the first and second light-emitting sources being capable of emitting different colors of light; and

(d) forming a first electrode on an exposed portion of the lower semiconductor layer exposed from the first and second epitaxial units, and forming at least two second electrodes respectively on the first and second epitaxial units opposite to the lower semiconductor layer.

### BRIEF DESCRIPTION OF THE DRAWINGS

Other features and advantages of the present invention will become apparent in the following detailed description of the preferred embodiments of the invention, with reference to the accompanying drawings, in which:

FIG. 1 is a schematic view illustrating the preferred embodiment of a light-emitting diode according to this invention;

FIG. 2 is a flow chart illustrating the preferred embodiment of a method for forming a light-emitting diode according to this invention;

FIG. 3 is a side view illustrating the light-emitting diode of FIG. 1 formed with a light-transmissive encapsulant; and

FIG. 4 is a schematic view illustrating a modified configuration of the preferred embodiment shown in FIG. 1.

### DETAILED DESCRIPTION OF THE PREFERRED EMBODIMENTS

Before the present invention is described in greater detail with reference to the accompanying preferred embodiments, it should be noted herein that like elements are denoted by the same reference numerals throughout the disclosure.

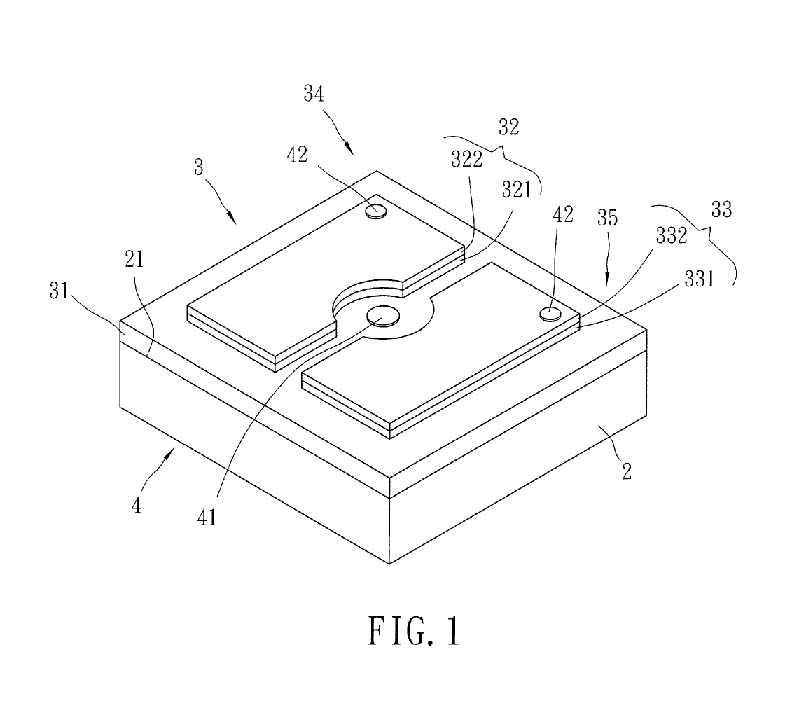

A method for forming a light-emitting diode (LED) according to this invention can provide multiple light-emitting sources in a single LED die of the LED. In the following preferred embodiment of this invention, an LED having two light-emitting sources is exemplified (see FIG. 1).

The LED of this invention comprises an epitaxial substrate 2, a light-emitting unit 3, and an electrode unit 4.

The epitaxial substrate 2 has an upper surface 21 and is made of a material selected from silicon, aluminum oxide and silicon carbide.

The light-emitting unit 3 includes a lower semiconductor layer 31 formed on and connected to the upper surface 21 of the epitaxial substrate 2, and first and second epitaxial units 32, 33 that are separately formed on the lower semiconductor layer 31. The first and second epitaxial units 32, 33 cooperate with the lower semiconductor layer 31 to define first and second light-emitting sources 34, 35 that are capable of emitting different colors of light. The first epitaxial unit 32 includes a first light-emitting film 321 and a first upper semiconductor film 322. The second epitaxial unit 33 includes a second light-emitting film 331 and a second upper semiconductor film 332. The first and second light-emitting films 321, 331 are separately formed on the lower semiconductor layer 31. The first and second upper semiconductor films 322, 332 are respectively formed on the first and second light-emitting films 321, 331 opposite to the lower semiconductor layer 31, and have an electrical property opposite to that of the lower semiconductor layer 31.

The lower semiconductor layer 31 is made of one of n-doped and p-doped semiconductor materials, and the first and second upper semiconductor films 322, 332 are made of the other one of the n-doped and p-doped semiconductor materials. That is to say, when the lower semiconductor layer 31 is made of the n-doped semiconductor material, the first and second upper semiconductor films 322, 332 are made of the p-doped semiconductor material, and vice versa. The first and second light-emitting films 321, 331 are made of different light-emitting materials. For example, the first light-emitting film 321 can be made of a material capable of emitting blue light, such as InₓGa₁₋ₓN, and the second light-emitting film 331 can be made of a material capable of emitting green light, such as In_{y}Ga_{1-y}N, wherein the amount of indium can be adjusted so that x is greater than y. The materials of the first and second upper semiconductor films 322, 332 can be selected based on the materials of the first and second light-emitting films 321, 331, and can be the same or different semiconductor material(s). As such, after electricity is supplied to the electrode unit 4, the first and second light-emitting sources 34, 35 are capable of emitting two colors of light. The lights from the first and second light-emitting sources 34, 35 are mixed to produce a predetermined color of light.

The electrode unit 4 include a first electrode 41 and two second electrodes 42. The first electrode 41 is formed on an exposed portion of the lower semiconductor layer 31 exposed from the first and second epitaxial units 32, 33, and is disposed between the first and second epitaxial units 32, 33. Each of the second electrodes 42 is formed on a corresponding one of the first and second epitaxial units 32, 33. The first and second electrodes 41, 42 can be electrically arranged so that the first and second light-emitting sources 34, 35 are capable of emitting light simultaneously. Alternatively, the first and second electrodes 41, 42 can be electrically arranged so that each of the first and second light-emitting sources 34, 35 can be driven to turn-on and turn-off individually. That is to say, the second electrodes 42 can be electrically isolated so that each of the first and second light-emitting sources 34, 35 can be driven to turn-on and turn-off individually. Otherwise, the second electrodes 42 can be electrically connected in series or in parallel so that the first and second light-emitting sources 34, 35 are capable of emitting light simultaneously. Since the electrical connections between the electrode unit 4 and an external power source (not shown) are well-known in the art, a detailed description thereof is omitted herein for the sake of brevity.

In addition, in order to prevent a short-circuit among the first and second electrodes 41, 42, the light-emitting diode of this invention may further include an insulating layer (not shown) formed to cover portions of the first and second upper semiconductor films 322, 332 that are exposed from the second electrodes 42, and to cover parts of the lower semiconductor layer 31 exposed from the first electrode 41 and the first and second epitaxial units 32, 33.

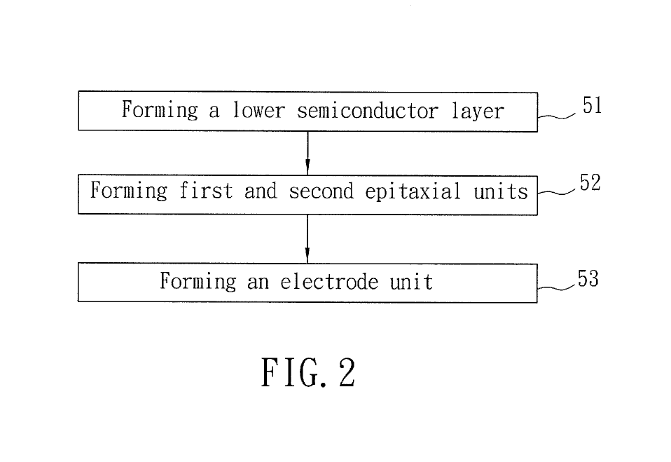

Referring to FIGS. 1 and 2, the preferred embodiment of a method for forming a light-emitting diode according to this invention includes the following steps.

In step 51, a lower semiconductor layer 31 is formed over an upper surface 21 of an epitaxial substrate 2 using a chemical vapor depositing process. In the embodiment, the lower semiconductor layer 31 is made of an n-doped semiconductor material.

In step 52, first and second epitaxial units 32, 33 are separately formed on the lower semiconductor layer 31 to obtain a light-emitting unit 3.

In detail, the first epitaxial unit 32 is formed by depositing a light-emitting material on a portion of an upper face of the lower semiconductor layer 31 to form a first light-emitting film 321.A first upper semiconductor film 322 is subsequently formed over the first light-emitting film 321. The first light-emitting film 321 and the first upper semiconductor film 322 are then downwardly and partially etched until the upper face of the lower semiconductor layer 31 is exposed. By the etching process, the first epitaxial unit 32 having a predetermined outline is obtained. The first epitaxial unit 32 and the lower semiconductor layer 31 define a first light-emitting source 34.

Next, a protective layer (not shown) made of silicon dioxide is formed on the first epitaxial unit 32. Then, the second epitaxial unit 33 is formed by depositing a material on the upper face of the lower semiconductor layer 31 to form a second light-emitting film 321 that is spaced apart from the first epitaxial unit 32. A second upper semiconductor film 332 is subsequently formed over the second light-emitting film 331. The second light-emitting film 331 and the second upper semiconductor film 332 are then downwardly and partially etched until the upper face of the lower semiconductor layer 31 is exposed. By the etching process, the second epitaxial unit 33 having a predetermined outline is obtained. The second epitaxial unit 33 and the lower semiconductor layer 31 define a second light-emitting source 35.

It should be noted that the first and second light-emitting films 321, 331 are made of different light-emitting materials to emit different colors of light. The first and second upper semiconductor films 322, 332 have an electrical property opposite to that of the lower semiconductor layer 31, and may be made of the same or different material(s). In this embodiment, the first and second upper semiconductor films 322, 332 are made of a p-doped semiconductor material. Since the suitable materials and the forming parameters for the light-emitting unit 3 are well-known in the art, detailed descriptions thereof are omitted herein for the sake of brevity.

In step 53, the protective layer is removed and an electrode unit 4 is formed.

In detail, the electrode unit 4 is obtained by forming a first electrode 41 on the upper face of the lower semiconductor layer 31 that is exposed from the first and second epitaxial units 32, 33 using a depositing process. Thereafter, two second electrodes 42 are formed respectively on the first and second upper semiconductor films 322, 332 of the first and second epitaxial units 32, 33.

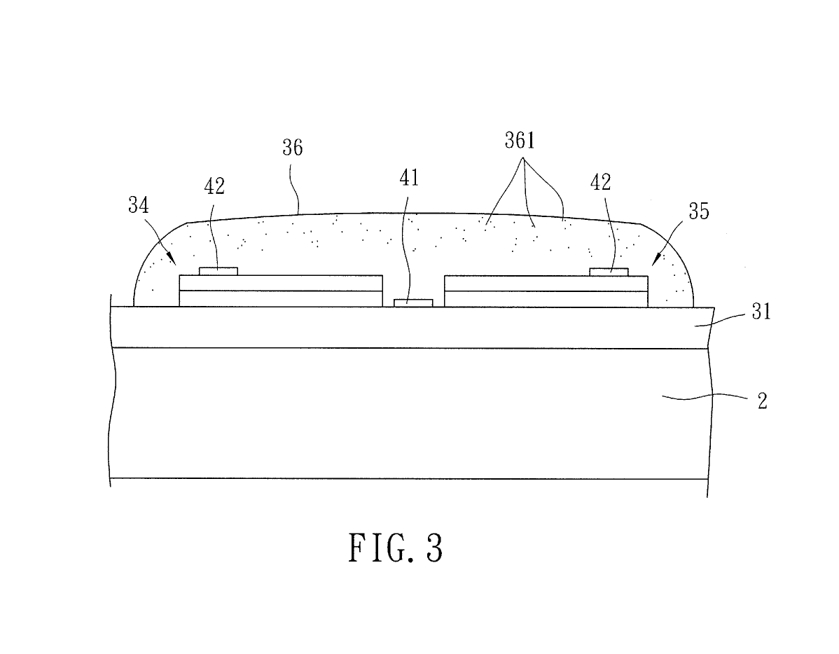

In another preferred embodiment, the method may further include a step of forming a light-transmissive encapsulant 36 to encapsulate the first and second epitaxial units 32, 33 (see FIG. 3). The light-transmissive encapsulant 36 is dispersed with fluorescent powders 361 that are adapted to produce excitation light in response to the light from at least one of the first and second light-emitting sources 34, 35. The excitation light has a color different from the colors of the light from the first and second light-emitting sources 34, 35. With the light-transmissive encapsulant 36, not only can the first and second epitaxial units 32, 33 be protected, but the excitation light can also be produced to adjust color of light emitting from the light-emitting unit 3. For example, when the first and second light-emitting sources 34, 35 can respectively emit blue light and yellow-green light to produce white light, the white light is slight greenish. Thus, with the fluorescent powders 361 adapted to produce a red excitation light, the light-emitting unit 3 may emit warm white light.

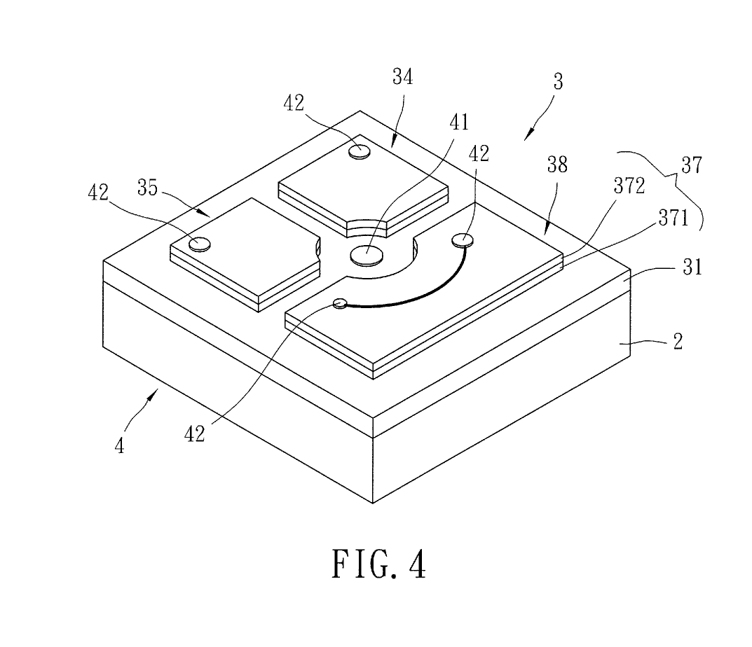

Alternatively, the light-emitting unit 3 may further include a third epitaxial unit 37 on the lower semiconductor layer 31 (see FIG. 4). The third epitaxial unit 37 is spaced apart from the first and second epitaxial units 32, 33, and is formed using a process similar to that for forming the second epitaxial unit 33. The third epitaxial unit 37 includes a third light-emitting film 371 formed on the lower semiconductor layer 31 and a third upper semiconductor film 372 formed on the third light-emitting film 371, and cooperates with the lower semiconductor layer 31 to define a third light-emitting source 38. Before forming the third epitaxial unit 37, another protective layer (not shown) is formed on the first and second epitaxial units 32, 33. After the third epitaxial unit 37 is formed, the protective layer on the first and second epitaxial units 32, 33 is removed.

Because the first, second and third epitaxial units 32, 33, 37 are formed separately, the colors of the light emitted from the first, second and third light-emitting sources 34, 35, 38 can be varied based on the materials for the first, second and third epitaxial units 32, 33, 37. Besides, by varying ratio among the sizes of the first, second and third epitaxial units 32, 33, 37, the light intensities of the first, second and third light-emitting sources 34, 35, 38 can also be varied, thereby adjusting the color of light emitted by the light-emitting unit 3.

In this embodiment, the first, second and third epitaxial units 32, 33, 37 are separately formed on the single epitaxial substrate 2 using multiple depositing processes to emit different colors of light. Thus, the LED of this embodiment may not encounter the problem of a conventional LED that is packaged with multiple LED dies therein. In addition, since the first, second and third light-emitting films 321, 331, 371 are disposed spaced apart from one another and emit light independently, the LED of this embodiment may have a relatively low threshold voltage (V_{f}) compared to the conventional LED having multiple light-emitting films stacked one above the other.

While the present invention has been described in connection with what are considered the most practical and preferred embodiments, it is understood that this invention is not limited to the disclosed embodiments but is intended to cover various arrangements included within the spirit and scope of the broadest interpretations and equivalent arrangements.

What is claimed is:

1. A light-emitting diode comprising:
an epitaxial substrate;
a light-emitting unit including a lower semiconductor layer, and at least two epitaxial units that are separately formed on said lower semiconductor layer, said epitaxial units cooperating with said lower semiconductor layer to define two light-emitting sources that are capable of emitting different colors of light; and
an electrode unit including a first electrode which is formed on an exposed portion of said lower semiconductor layer exposed from said epitaxial units, and at least two second electrodes each of which is formed on a corresponding one of said epitaxial units.

2. The light-emitting diode of claim 1, wherein said light-emitting unit includes three of said epitaxial units, said epitaxial units cooperating with said lower semiconductor layer to define three of said light-emitting sources that are capable of emitting different colors of light.

3. The light-emitting diode of claim 1, further comprising a light-transmissive encapsulant that encapsulates said light-emitting unit.

4. The light-emitting diode of claim 3, wherein said light-transmissive encapsulant is dispersed with fluorescent powders that are adapted to produce excitation light in response to the light from at least one of said light-emitting sources.

5. The light-emitting diode of claim 1, wherein each of said epitaxial units includes a light-emitting film formed on said lower semiconductor layer, and an upper semiconductor film that is formed on said light-emitting film opposite to said lower semiconductor layer, and that has an electrical property opposite to that of said lower semiconductor layer.

6. The light-emitting diode of claim 1, wherein said light-emitting sources are capable of emitting light simultaneously.

7. The light-emitting diode of claim 1, wherein each said light-emitting sources can be driven to turn-on and turn-off individually.

8. A method for forming a light-emitting diode comprising:
(a) forming over an epitaxial substrate a lower semiconductor layer;
(b) forming a first epitaxial unit on the lower semiconductor layer, the first epitaxial unit and the lower semiconductor layer defining a first light-emitting source;
(c) forming a second epitaxial unit on the lower semiconductor layer in a manner that the first and second epitaxial units are spaced apart from each other, the second epitaxial unit and the lower semiconductor layer defining a second light-emitting source, the first and second light-emitting sources being capable of emitting different colors of light; and
(d) forming a first electrode on an exposed portion of the lower semiconductor layer exposed from the first and second epitaxial units, and forming at least two second electrodes respectively on the first and second epitaxial units opposite to the lower semiconductor layer.

9. The method of claim 8, further comprising, before step (c), (e) forming a first protective layer on the first epitaxial unit, and (f) removing the first protective layer before step (d).

10. The method of claim 9, further comprising, before step (d):
(g) forming a second protective layer on the second epitaxial unit;
(h) forming a third epitaxial unit on the lower semiconductor layer in a manner that the first, second and third epitaxial units are spaced apart from one another, the third epitaxial unit and the lower semiconductor layer defining a third light-emitting source, the first, second and third light-emitting sources being capable of emitting different colors of light; and
(i) removing the second protective layer.

11. The method of claim 10, wherein each of the first, second and third epitaxial units includes a light-emitting film formed on the lower semiconductor layer, and an upper semiconductor film that is formed on the light-emitting film opposite to that of the lower semiconductor layer, and that has an electrical property opposite to that of the lower semiconductor layer.

12. The method of claim 8, further comprising:
(j) forming a light-transmissive encapsulant to encapsulate the first and second epitaxial units.

13. The method of claim 12, wherein the light-transmissive encapsulant is dispersed with fluorescent powders that are adapted to produce excitation light in response to the light from at least one of the first and second light-emitting sources.

14. The method of claim 8, wherein the first and second light-emitting sources are capable of emitting light simultaneously.

15. The method of claim 8, wherein each of the first and second light-emitting sources can be driven to turn-on and turn-off individually.
